(19) United States
(12) Patent Application Publication
(10) Pub. No.: US 2007/0276616 A1
(43) Pub. Date: Nov. 29, 2007

(54) Identifying a Reference Point in a Signal

(75) Inventor: Martin S. Wilcox, Redhill (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/573,289

(22) PCT Filed: Aug. 8, 2005
(86) PCT No.: PCT/IB05/52630

§ 371 Date: Feb. 6, 2007

(30) Foreign Application Priority Data
Aug. 10, 2004 (GB) 0417717.6

(51) Int. Cl. G06F 19/00; G01R 23/00

(52) U.S. Cl. 702/73; 331/25

(57) ABSTRACT

A transmitter device (1), operable to perform distance measurements by using time-of-flight measurements, has a sampling frequency different to the frequency of a time-of-flight signal sent from the transmitter device to a receiver device (12) in order for the distance between the transmitter device (1) and the receiver device (12) to the determined. The signal, from which the time-of-flight signal is derived, is modulated with a PRN sequence derived from the output signal of a Numerically Controlled Oscillator (17). A new chip is generated by the NCO (17) each time a register (24) in the NCO overflows, but the beginning of the chip according to the desired frequency of the PRN code does not necessarily coincide with a sampling point in the transmitter device (1). The invention enables time stamps to be generated even when the reference point (30) to be timed does not coincide exactly with a sampling point (31, 32) in the transmitter and consequently the time-of-transmission of the time-of-flight signal can be determined accurately. The time-stamp for a reference point (30) is constituted by the residual phase code (34) in the register (24) of the NCO (17) immediately following the reference point. The difference between the fixed value added to the register (24) at each sampling point and the recorded residual phase code (34) at the sampling point (32) immediately following the reference point (30) is proportional to the time passed between the sampling point (31) prior to the reference point (30) and the reference point (30).

The invention relates to: a method of identifying a reference point in a signal occurring in a device; to a method of calculating a measure of the distance between a transmitter and a receiver, and to a method of calculating a measure of the distance between a transmitter and a receiver. The invention also relates to a device comprising a recorder arranged to record the value of a register in the NCO; to a system for calculating a measure of the distance between a transmitter and a receiver device, and to a receiver device operable to calculate a measure of the distance between a transmitter and the receiver device from a received signal transmitted by the transmitter.

A known system using time-of-flight measurements to determine distance between two devices is the Global Positioning System (GPS). A GPS satellite transmits a sequence using a Direct Sequence Spread Spectrum technique. When a received receives the signal, a locally generated code can be correlated with the recited satellite signal to determine the distance between the two devices. By finding the distance to an additional three GPS satellites, and using trilateration, the position of the receiver and the offset of the local clock from the satellite clock can be found. Usually, further GPS satellites are used for additional accuracy. GPS receivers typically are dedicated devices and consequently, the internal processes and clock frequencies are selected to match the frequency of the time-of-flight signal modulated onto the satellite signal.

It has been proposed that implementation of time-of-flight functions, similar to GPS technology, in existing radio devices, such as mobile phones and wireless data processing devices, may have many advantages. Not only can the user of such a device determine its exact location on earth, by performing time-of-flight measurements with devices having fixed locations, but the relative distance between two moving devices can also be determined. Moreover, if the radio device constitutes a node in a network of similar devices, the network can update itself depending on the relative distances between the devices. However, existing radio devices were not developed with consideration to location finding systems and, thus, they do not use the same standards. In particular, the frequency of the signals generated by the system clocks of the radio devices may not match the frequency of the time-of-flight signals used in the location finding systems. There may be a price advantage in using a commodity crystal with a common frequency in the radio device, even though its frequency may not be ideal for the time-of-flight application.

Accurate range measurements may also be important in wireless, large, short-range networks. An example of such a network is a network for a smart home, operating according to the ZigBee standard (www.zigbee.org). The communication range of the devices of such a network is short and, consequently, two devices operating within the same network may not be in communication range of each other. However, messages can still be sent between the two nodes, with the help of additional nodes within communication range of both nodes. To increase the security and reliability of the data transfer, suitable routes between the two devices needs to be computed, and to this end, can be useful to know the distance between nodes in the network. Moreover, a proportion of the nodes in these types of network can be mobile and, consequently, the distance measurements need to be updated repeatedly. Since distance between neighbouring devices may be a few metres, an error of a few nanoseconds in the time-of-flight measurements may result in unreliable distance measurements, which can be important if devices have a short communication range.

It is known in the art to use Numerically Controlled Oscillators (NCO) to produce periodic signals with frequencies different from the frequency of the system clock. U.S. Pat. No. 6,650,150 discloses an NCO for use in a radiofrequency signal receiver. However, even though signals approximating the time-of-flight signals used in GPS technology can be produced, the assumed edges of the signal will not necessarily coincide with sampling points in the signal derived from the system clock. This poses a problem when determining the time-of-transmission of a time-of-flight signal, which is typically set as the beginning of a chip of a direct spectrum code in the time-of-flight signal. If the frequency of the sampling signal, derived from the system clock, is the same as or is a multiple of the frequency of the pseudorandom noise sequence to be sent, the assumed time at which the first chip in each frame or sub-frame in the transmitted time-of-flight signal occurs can be arranged to coincide with a clock edge of the sampling signal. The time of transmission of the first chip in a frame can subsequently be calculated by counting the number of samples between a reference time and the clock edge coinciding with the chip and multiplying the number of counted samples with the period of the sampling signal. If the frequency of the sampling signal is not an integer multiple of the frequency of the pseudorandom noise sequence the time-of-transmission of the first frame is likely to fall between two clock edges of the sampling signal and thus, the time of transmission can only be determined approximately. The uncertainty in the time measurement may result in a particularly large proportional error if the distance between the transmitting and receiving node is short.

Moreover, the uncertainty in the time-of-transmission data increases with decreasing sampling frequency if the time-of-transmission has to be approximated to the nearest sampling instant. This problem would be overcome if the sampling rate was increased sufficiently but it is not usually feasible or cost-effective to provide suitably high sampling frequencies.

The invention seeks to mitigate these problems.

According to a first aspect of the invention, there is provided a method of identifying a reference point in a signal occurring in a device, the device including an oscillator arranged to provide a sampling signal at a first frequency, the method comprising

using the sampling signal to control a NCO to provide at an output an NCO output signal approximating a regular signal having a second frequency, and

recording the value of a register in the NCO at a time derived from the sampling signal following the reference point.

In embodiments described in detail hereinafter, the reading step comprises reading the value of the register in the NCO at the sampling point immediately following the reference point. However, it will be appreciated that in some implementations the reading step may comprise reading the value of the register in the NCO at a sampling point a small number of samples following the reference point.

The device may be a transmitter, in which case the signal is generated by the transmitter, and the method further comprises transmitting a signal derived from the NCO output signal.

The device need not be a transmitter. Indeed, the invention is applicable to signals occurring also in receivers and in other devices, as will be appreciated by the skilled person.

The method may further comprise using the recorded value of the register to derive a clock time in the device at the reference point.

Alternatively, the method may further comprise transmitting a message to a receiver wherein the message contains information to allow the time-of-transmission of the reference point in the signal to be calculated at the receiver. In this case, the information may either include identification of a fraction of sample period, the fraction being indicative of the timing of the reference point relative to a sampling point, or alternatively include a value of register at the sampling point and the sampling increment.

The clock time typically will be referred to some reference time, by way of a count of the number of sampling instances or the number of chips since that reference time, and by way of the data from which the fraction of the sampling interval can be determined. The exact way of representing the reference to the reference time is not critical to the invention.

According to a second aspect of the invention, there is provided a method of calculating a measure of the distance between a transmitter and a receiver, the method comprising:

at a transmitter, identifying a reference point in a signal as recited above, and

at the receiver:
receiving the transmitted signal;
determining the local time of reception of the reference point in the signal;
receiving from the transmitter an indication of a clock time at the transmitter at the reference point; or
receiving from the transmitter a message including:
   an indication of a fraction of a sample period at the transmitter, the fraction being indicative of the timing of the reference point relative to a sampling point, or
   an indication of the value of the register; and
   using the message to derive a clock time at the transmitter at the reference point; and
using the transmitter clock time and the local reference point reception time to calculate the measure of the distance between the transmitter and the receiver.

According to a third aspect of the invention, there is provided a method of calculating a measure of the distance between a transmitter and a receiver, the method comprising at the receiver:

receiving a signal transmitted by the transmitter;

determining the local time of reception of a reference point in the signal;

receiving a message including:
an indication of a fraction of a sample period at the transmitter, the fraction being indicative of the timing of the reference point relative to a sampling point, or
an indication of the value of a register in an NCO of the transmitter at a sampling point following the reference point and a sampling increment of the NCO;

using the message to derive a clock time at the transmitter at the reference point; and

using the derived transmitter clock time and the local reference point reception time to calculate the measure of the distance between the transmitter and the receiver.

The sampling increment in the embodiments is an add-word.

The second and third aspects of the invention allow the distance between the transmitter and the receiver to be calculated with greater resolution than would be possible if the transmitter were not able to identify the reference point other than at sampling instances.

Advantageously, in any of the above methods the signal includes a PRN code having a chip period related to the second frequency.

According to a fourth aspect of the invention, there is provided a device comprising:

a source of oscillation arranged to provide a sampling signal at a first frequency,

an NCO configured to use the sampling signal to provide at an output an NCO output signal approximating a regular signal having a second frequency; and

a recorder arranged to record the value of a register in the NCO at a time derived from the sampling signal and following a reference point, thereby to allow the reference point in the signal to be identified.

According to a fifth aspect of the invention, there is provided a system for calculating a measure of the distance between a transmitter and a receiver device,

the transmitter being a device as described above, and

the receiver comprising:
receiver means for receiving the transmitted signal;
a processor arranged to determine the local time of reception of the reference point in the signal;
the receiver being arranged either:
   to receive from the transmitter an indication of a clock time at the transmitter at the reference point; or
   to receive from the transmitter a message including:
      an indication of a fraction of a sample period at the transmitter, the fraction being indicative of the timing of the reference point relative to a sampling point, or
      an indication of the value of the register; and
      the receiver being arranged to use the message to derive a clock time at the transmitter at the reference point; and
the processor being arranged to use the transmitter clock time and the local reference point reception time to calculate the measure of the distance between the transmitter and the receiver.

According to a sixth aspect of the invention, there is provided a receiver device operable to calculate a measure of the distance between a transmitter and the receiver device from a received signal transmitted by the transmitter, the receiver device comprising:

a processor arranged to determine the local time of reception of a reference point in the signal;

a receiver arranged to receive from the transmitter a message including:
an indication of a fraction of a sample period at the transmitter, the fraction being indicative of the timing of the reference point relative to a sampling point, or
an indication of the value of a register in an NCO of the transmitter at a sampling point following the reference point and a sampling increment of the NCO;

the processor being arranged to use the message to derive a clock time at the transmitter at the reference point, and to use the derived transmitter clock time and the local reference point reception time to calculate the measure of the distance between the transmitter and the receiver.

Embodiments of the present invention will now be described, by way of example, with reference to the accompanying drawings, in which

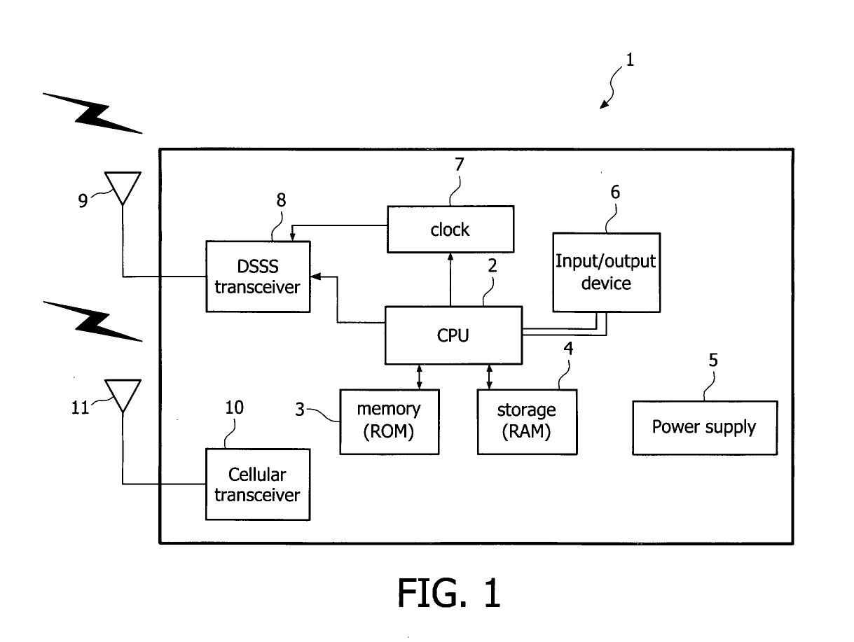

FIG. 1 is a schematic diagram of the components of a device in which aspects of the invention may be implemented;

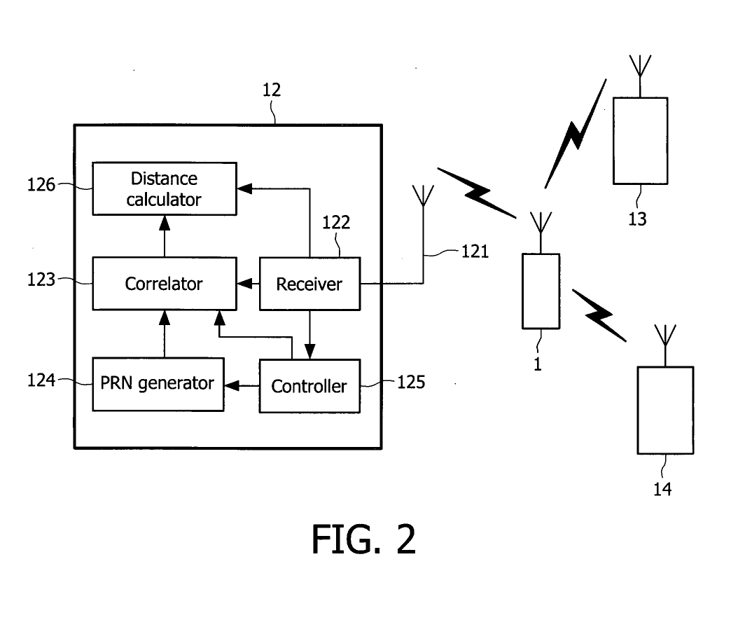

FIG. 2 shows a network of devices in which various aspects of the invention may be used;

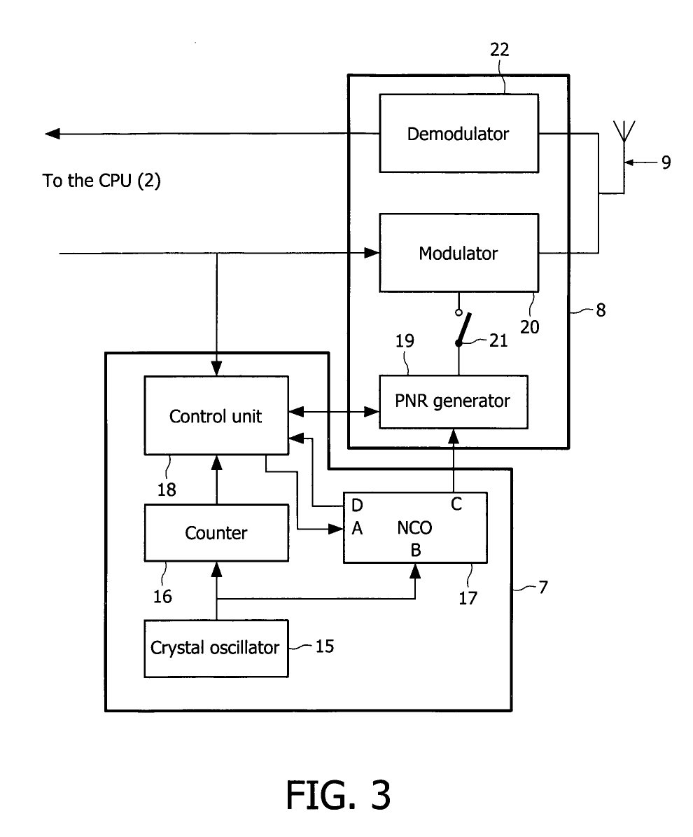

FIG. 3 is a schematic diagram of subcomponents of the FIG. 1 device;

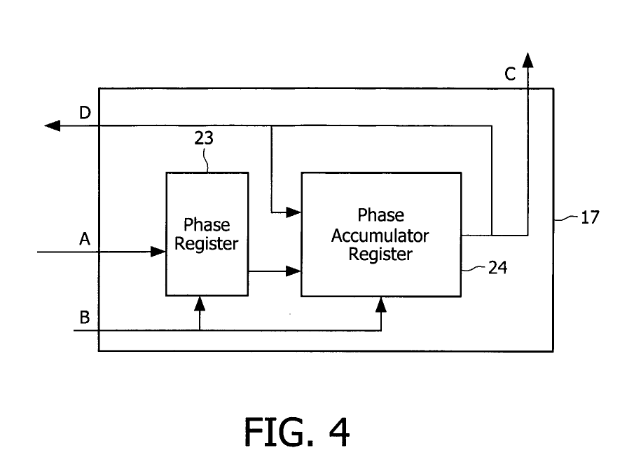

FIG. 4 is a schematic diagram of subcomponents of a Numerically Controlled Oscillator;

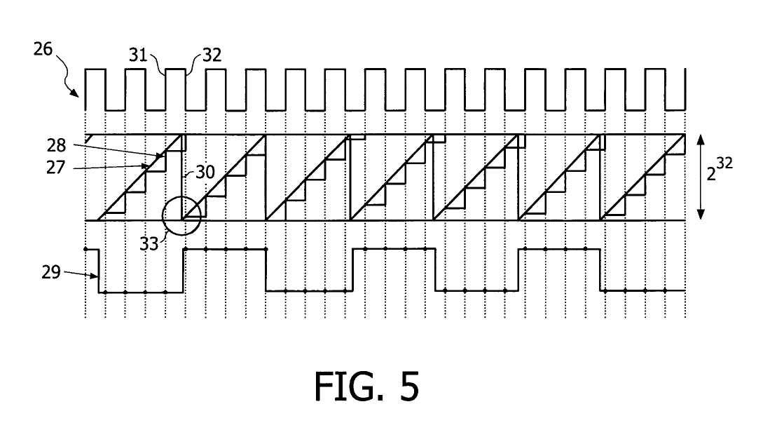

FIG. 5 illustrates how the time-of-transmission can be determined, according to one embodiment of the invention;

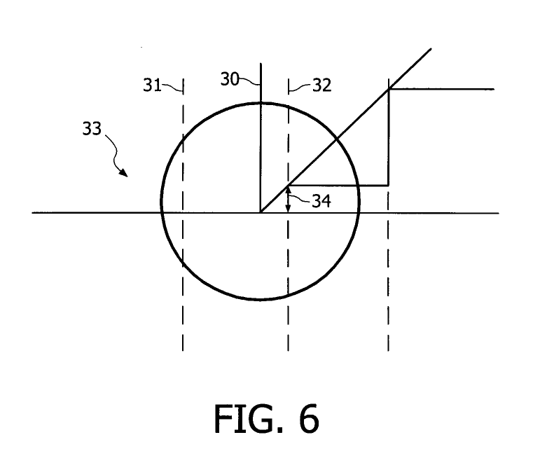

FIG. 6 is an enlarged view of a region in FIG. 5; and

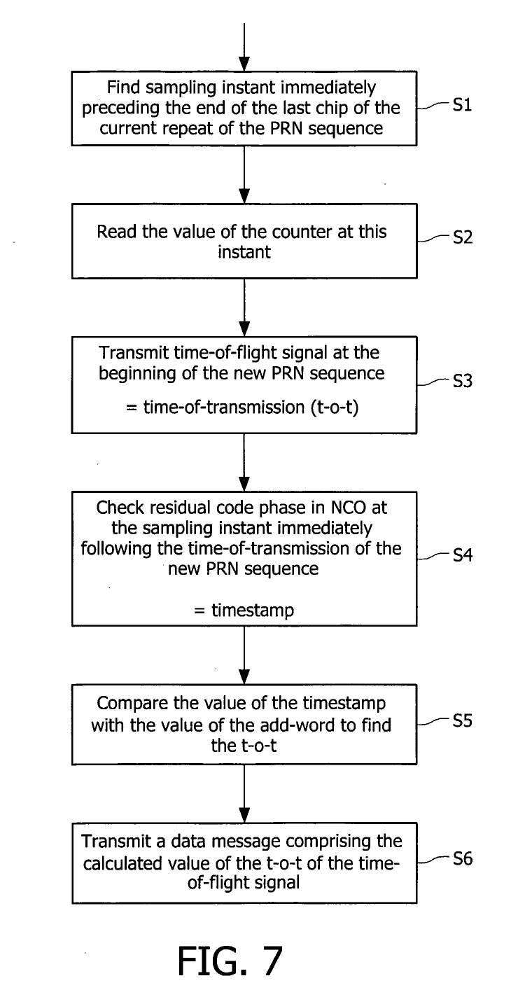

FIG. 7 illustrates the steps of the method according to one embodiment of the invention.

FIG. 1 shows a radio device in which the invention may be implemented. The device transmits and receives messages using the Direct Sequence Spread Spectrum (DSSS) technique. The device 1 has a central processing unit (CPU) 2, a read-only memory (ROM) 3, a random access memory (RAM) 4, a power supply 5 and an input/output device 6 for interacting with a user. The power supply 5 may be in the form of a battery. The device 1 further has a clock 7 for timing internal processes and for synchronising internal processes with other devices. A DSSS transceiver unit 8 is connected to both the clock 7 and the central processing unit 2. An antenna 9 transmits radio signals provided by the DSSS transceiver 8. In brief, the DSSS transceiver unit 8 operates to transmit signals over a range of frequencies, thereby making the signal more resistant to noise, interference and eavesdropping. The DSSS transceiver unit generates a pseudorandom code of 1s and 0s, called a pseudorandom noise (PRN) sequence and uses this sequence to modulate a carrier frequency signal. The PRN sequence may have a bandwidth of 1 MHz centred on the frequency of the carrier signal. At the receiving end, the receiver shifts a replica of the PRN code in time until there is correlation between the replica and the received PRN code. When a correlator has a peak output, there is deemed to be optimal alignment of the PRN codes. The DSSS transceiver may be a ZigBee™ transceiver able to communicate data over a short range radio link to other ZigBee devices.

If the device is implemented in a cellular phone, the device further comprises a transceiver 10 and an antenna 11 for receiving and transmitting signals over the cellular network. In an alternative embodiment, the cellular transceiver is integrated with the DSSS transceiver 8 and a single antenna is shared between the two transceivers.

FIG. 2 shows a mobile station comprising device 1 in communication with three base stations 12, 13 and 14. The signals sent between the mobile station and the devices 12, 13 and 14 allow for the exact position of the mobile station to be determined through time-of-flight calculations. These signals can be termed time-of-flight signals. When the base-station 12 receives the time-of-flight signal from the mobile station, a local replica of the PRN code is correlated with the PRN code modulated onto the time-of-flight signal and the time of arrival of the time-of-flight signal is determined as the starting point in time of the replica when full correlation between the received and the local code occurs. The derived value of the time-of-arrival and the received value for the time-of-transmission are used to find the distance between the base station 12 and the mobile station 1. The subcomponents of the receiver involved in deriving the time-of-flight value are described in more detail below. In order to find the absolute position of the mobile station, time-of-flight measurement may also be determined between the mobile station and each of base stations 13 and 14. When all three distances are known and the location of the base stations 12-14 are known, the absolute position of the mobile station can be found by trilateration.

The system of FIG. 2 may instead comprise a number of nodes in a ZigBee network. In this case, it may not be necessary to determine the location of any node. Indeed, all the nodes may be mobile. Instead, the distance between any two nodes may be required to be calculated, so that it can be determined whether communication should be effected between those two nodes directly or via one or more intermediate nodes. Distance measurements may also be useful for other purposes. For example, detection of a node carried by a user exceeding a preset distance from a security node may initiate the setting of a security system.

FIG. 3 shows the subcomponents of the clock 7 and the DSSS transceiver unit 8 according to one embodiment of the invention. The clock 7 comprises a crystal oscillator 15, for example a 13 MHz crystal oscillator, a counter 16, a numerically controlled oscillator (NCO) 17, having input and output lines A-D, and a control unit 18. The counter 16 counts every clock edge following a reference time. The crystal oscillator 15 and the counter 16 constitute the system clock. A sampling signal is derived from the signal generated by the crystal oscillator 15. The NCO 17 is operated to generate a signal that approximates regular periodic signal for transmission using the transceiver 8. The output signal of the NCO 17 is likely to have a frequency different to the frequency of the input signal. Thus, the NCO 17 is able to create a signal having a frequency suitable for time-of-flight measurements even if the system clock has a frequency which is not suitable. The output signal is used for producing the PRN chip sequence at the appropriate chip rate. Because of the differences between the frequencies of the two signals, the reference points of the ideal DSSS signal approximated by the output of the NCO 17 may not coincide with the edges of the clock signal. The method of marking the time of reference points in the DSSS signal falling between two sampling instants relies on the periodic signal for the PRN code being generated using an NCO 17.

The regular periodic signal generated by the NCO 17 is passed to the DSSS transceiver unit 8 comprising a PRN generator 19, a modulator 20, a gate 21 and a demodulator 22. The PRN generator produces a 1 or 0 for every chip of the spreading sequence in order to produce the PRN sequence. The chip is the smallest elemental component of the PRN spreading sequence. Ideally, the length of each chip in the output signal of the NCO would be constant and have a duration corresponding to the chip in an ideal time-of-flight signal. However, due to the frequency of the sampling signal provided by the oscillator 15, some chips may be longer and some chips may be shorter than the assumed chip length defined by the ideal DSSS signal. However, the average frequencies are the same, even if there are some differences as to when edges occur. Moreover, due to the technique by which the output signal is created in the NCO, a virtual starting point of a chip in the output signal, corresponding to the starting point of the corresponding chip in the ideal DSSS signal, can be identified or calculated and thereby the corresponding point in the transmitted signal can be accurately determined.

The PRN sequence is repeated for each subframe. The time equating to the beginning of the first chip of the new PRN sequence is hereafter termed a reference point. This reference point constitutes the time-of-transmission (t-o-t) even though that chip will not actually be transmitted until the next sampling instance. The control unit further forwards the t-o-t to the modulator such that a message informing the receiver of the time-of-transmission can be transmitted. Alternatively, it may forward the t-o-t to the CPU and the CPU then forwards a message comprising the t-o-t to the modulator for transmission.

The message including information indicating the time-of-transmission of the time-of-flight signal can be modulated onto a time-of-flight signal transmitted by the DSSS transceiver 8. The message can either be modulated onto the DSSS signal to which it refers, in which case the message could say “This spreading code sequence began at time XXXX”, or it can be sent at some time later, in which case the message could say “The previous spreading sequence began at time XXXX”. Alternatively, the message may be transmitted using other means, for example a second transmitter not using the DSSS technique. If a substantial number of DSSS signals are sent in the system, the message may include information identifying the DSSS signal to which the message refers.

The DSSS transceiver 8 can also receive DSSS signals. This allows bidirectional communication between the receiver and the transmitter of DSSS signals. An incoming signal is sampled at the sampling frequency of the system clock and then demodulated in the demodulator 22. The process of demodulating a DSSS signal is described in more detail below in the context of the processes carried out in the receiver when a DSSS signal is received.

Referring again to FIG. 2, the subcomponents of the receiver device 12 are shown. The receiver device comprises an antenna 121 and a DSSS receiver 122 for receiving the transmitted signal. In the DSSS receiver, the incoming signal is sampled at the rate of the receiver system clock. The sampling rate is typically larger than the chip rate of the PRN code; thus, the signal is over-sampled. However, the local clock of the receiver does not necessarily have the same frequency as the local clock of the transmitter and the two clocks are unlikely to be transmitted. Thus, the beginning of each chip in the received signal is not known and has to be deduced by extrapolating the sampled values and considering the expected frequency of the PRN code. The time-of-arrival of the signal is therefore determined as the time-of-arrival of the reference point. In order to find the time-of-arrival, receiver 122 forwards the sampled values of the signal to the correlator 123. The correlator compares the sampled values with a replica of the PRN code generated by the PRN generator 124. A controller 125 controls the operation of the PRN generator 124 and the correlator 123. The correlation between the PRN replica and the sampling instant is first compared with the reference point of the PRN replica located at an approximate time-of-arrival time. The PRN replica is then shifted in time by small increments until full correlation occurs between the signals. The time-shift of the replica added to the approximate time-of-arrival time constitutes the accurate time-of-arrival of the reference point.

The receiver 122 also receives a message from the transmitter device including information about the time-of-transmission. The information may either be an indication of the calculated time-of-transmission or a time stamp allowing the receiver to calculate the time-of-transmission. The information is forwarded to the distance calculator 126 that derives the time-of-transmission from the received information The distance calculator also receives the time-of-arrival information from the correlator allowing it to determine the accurate time-of-arrival. Using the time-of-transmission and the time-of-arrival the distance calculator 126 determines the time-of-flight of the signal and consequently the distance between the receiver and the transmitter.

The subcomponents of the NCO 17, shown in FIG. 4, comprise, in brief, a phase register 23 and a phase accumulator register 24. A predetermined binary word, known as the add-word, is placed in the phase register 23. The value of the add-word can be changed in order to obtain different NCO output frequencies. In this example, the control unit 18 is connected to input A and can change the value of the add-word in the phase register 24. At each sampling instant the add-word in the phase register 23 is added to the value in the phase accumulator register 24. The phase accumulator resister 24 also comprises output lines connected to the input of said phase accumulator register 24, such that at each sampling instant, a number of output bits in parallel on said lines are added to the input bits from the phase register 23. Thus, for each sampling instance, the value in the phase accumulator register 24 is incremented by one add-word. Every time the value in the phase accumulator register 24 reaches a threshold value, i.e. the incremented value in the register exceeds the highest number representable by the number of bits in the phase accumulator register 24, the phase accumulator register 24 overflows. On the sampling instant on which the phase accumulator register 24 overflows, an edge is generated in the output signal of the NCO. At this time, the residual phase value, i.e. the remainder of the incremented value when the threshold value is subtracted, is left in the phase accumulator register 24.

The clock signal generated by the NCO is derived from the value of the Most Significant Bit in the phase accumulator register. The Most-Significant Bit (MSB) resets to zero after each overflow, it changes to 1 about half-way through the chip and then resets to zero again at the next overflow. A new chip in the PRN sequence, generated by the PRN generator 19, is triggered at each falling edge of the MSB. A signal, communicating the sampling instant on which the falling edge of the MSB occurs is sent, via output C of the NCO 17, to a shift register (not shown) of the PRN generator 19. The value of a number of the Least-Significant Bits (LSBs) of the register is communicated by a signal, sent via output D, to the control unit 18, such that the residual value of the accumulator register 24 can be determined on sampling instants immediately following overflow.

A typical NCO contains a 32-bit register and thus, the threshold value is equal to 2³². The value of the add-word stored in the phase register 23 and added to the accumulator register at each sampling instant determines the frequency of the output signal of the NCO 17. If the value is small, it takes longer to fill up the accumulator register and the output frequency is low. If the value is large, the accumulator gets filled up in a number of clock cycles and the output frequency is relatively high. The add-word is given by
add-word=(f_{c}*2³²)/fₛ eq. 1
where fₛ is the sampling rate of the input signal (i.e. the clock frequency) and f_{c} is the desired rate of the output signal (i.e. the chip frequency). The phase accumulator resister 24 operates on integers only and, thus, the add-word is rounded to the closest integer value.

FIG. 5 shows the sampling signal 26 from the crystal oscillator 13. The sampling signal 26 has a frequency fₛ. It also shows the residual code phase 27 and 28 in the phase accumulator register 24 and the spreading code 29 of the PRN generator. The residual code phase 28 clearly shows how the value in the phase accumulator register 24 is incremented at every sampling point. The line 27 in effect shows how the value in the accumulator register would increase if the sampling rate was dramatically increased. The residual code-phase in the phase accumulator register 24 at the sampling instant immediately following the overflow indicates when the overflow would have occurred had there been an infinite sampling frequency. The time of the virtual overflow of the register will from hereinafter be referred to as the virtual overflow time. Each virtual overflow time corresponds to the edge of a chip in an ideal DSSS signal, wherein all chips have equal length. The ideal DSSS signal generated by the PRN generator is shown by line 29. Here, the amplitude of the signal 29 changes at each virtual overflow time. In the actual DSSS signal, the edge does not occur until the following sampling instant. However, by measuring the residual value in the register 24 immediately on overflow, the virtual overflow time can be determined.

FIG. 6 shows the region 33 magnified. The virtual overflow time 30 occurs between two sampling instants 31 and 32. The value of the register at sampling instant 32 is shown by reference numeral 34. The value of an add-word minus the residual code phase value 34 is proportional to the time between the sampling instant 31 and the virtual overflow 30. Put another way, the value of an add-word minus the residual code phase value 34 compared to the threshold value identifies the fraction of a chip period which has passed between the sampling instant and the virtual overflow time 30. Thus, the residual code phase value 34 constitutes a time stamp for the virtual overflow time 30. The time of transmission can thus be calculated as the time corresponding to the residual phase accumulator value at the sampling instant 31 plus the time passed between the sampling instant 31 and the virtual overflow 30.
t-o-t=(counter value)/fₛ+(add word−time stamp)/(f_{c}*2³²) eq. 2

Hence, the assumed time of transmission of the leading edge of the corresponding chip can be determined to a higher accuracy than if it was approximated to the nearest sampling instant.

Experiments have shown that when using sampling rates of a few 10s of MHz, the time-of-transmission can be measured using this scheme with nanosecond accuracy. Considering that the radio signals travel approximately 30 cm per nanosecond, the accuracy of the time-of-flight measurement provided by the invention allows distance measurements between devices accurate to a few 10s of centimetres to be obtained. This is the case even though a standard 13 MHz crystal oscillator is used.

A method for finding the time-of-transmission of a DSSS signal between two devices is illustrated by FIG. 7. The PRN generator 19 in both devices continuously generate a PRN sequence. When a DSSS signal is transmitted, the control unit 18 identifies the end of one PRN sequence from which the beginning of the next sequence can be inferred. In step S.1, the last sampling instant before the overflow in the phase accumulator register 14 that generates the last chip of the current PRN sequence is identified. This sampling instant corresponds to sampling instant 31 in FIGS. 4 and 5. The value in the counter 16 is detected at this instant as shown in Step S.2. The DSSS transmitter 8 starts sending the signal at the next overflow of the register (S. 3). However, the time-of-transmission of the DSSS signal is set to be the virtual overflow time of the register 24 since that instant corresponds to the beginning of the first chip of the new PRN sequence in an ideal DSSS signal. In Step S. 4 the sampling instant immediately following the time-of-transmission is identified, and the residual code phase in the phase accumulator register 24 is read. This and the value in the counter constitute the time stamp for the time-of-transmission. Subsequently, in step S.5 the time of transmission is found by comparing the value of the time stamp with the value of the add-word according to equation 2. Finally, in step S.6 the calculated time-of-transmission is transmitted to be received by the second device. The second device determines the time-of-arrival according to its local clock, and then calculates the time-of-flight of the signal.

In an alternative embodiment, the transceiver does not send a digital word representing the Time-of-transmission. Instead, it sends two digital words, one representing the count of the number of samples since a reference time at sampling instant 26, and one representing the fractional part of the time-of-transmission in units of time. In a third alternative embodiment, three digital words are sent, one representing the count of the number of samples since the reference time one containing the timestamp and the add-word, allowing the receiver to calculate the time-of-transmission. In this case, the calculation of eq. 2 is carried out in the receiver.

Although in the embodiments of the invention described, the invention is implemented in DSSS transceivers, the invention could be applied to any digital transceiver in which the transmitted waveform is generated using an NCO. Thus, for example, the invention could be used in a network of nodes constituted by Bluetooth devices. In this case, range measurements may be useful, since some fixed Bluetooth nodes may be interested in the distance between themselves and one or more mobile nodes, so that they can determine whether or not to deliver location-specific content to a given mobile device.

Although Claims have been formulated in this Application to particular combinations of features, it should be understood that the scope of the disclosure of the present invention also includes any novel features or any novel combination of features disclosed herein either explicitly or implicitly or any generalisation thereof, whether or not it relates to the same invention as presently claimed in any Claim and whether or not it mitigates any or all of the same technical problems as does the present invention. The Applicants hereby give notice that new Claims may be formulated to such features and/or combinations of such features during the prosecution of the present Application or of any further Application derived therefrom.

1. A method of identifying a reference point (30) in a signal occurring in a device (1), the device including an oscillator (15) arranged to provide a sampling signal (26) at a first frequency, the method comprising
using the sampling signal (26) to control an (17) NCO to provide at an output an NCO output signal approximating a regular signal having a second frequency, and
recording the value (34) of a register (24) in the NCO (17) at a time (32) derived from the sampling signal following the reference point.

2. The method of claim 1, in which the device (1) is a transmitter, and the signal is generated by the transmitter, the method further comprising transmitting a signal derived from the NCO output signal.

3. The method of claim 1, further comprising using the recorded value (34) of the register (24) to derive a clock time in the transmitter (1) at the reference point (30).

4. The method of claim 1, further comprising transmitting a message to a receiver (12) wherein the message contains information to allow the time-of-transmission of the reference point in the signal to be calculated at the receiver.

5. The method of claim 4, wherein the information includes identification of a fraction of sample period, the fraction being indicative of the timing of the reference point (30) relative to a sampling point (31).

6. The method of claim 4, wherein the information includes the value of the register (24) at the sampling point (32), and the sampling increment.

7. A method of calculating a measure of the distance between a transmitter (1) and a receiver (12), the method comprising:
at a transmitter (1), identifying a reference point (30) in a signal as claimed in claim 2, and
at the receiver (12):
receiving the transmitted signal;
determining the local time of reception of the reference point in the signal;
receiving from the transmitter an indication of a clock time at the transmitter at the reference point; or
receiving from the transmitter a message including:
an indication of a fraction of a sample period at the transmitter, the fraction being indicative of the timing of the reference point (30) relative to a sampling point (31), or
an indication of the value of the register (34) and a sampling increment of the NCO; and
using the message to derive a clock time at the transmitter at the reference point; and
using the transmitter clock time and the local reference point reception time to calculate the measure of the distance between the transmitter (1) and the receiver (12).

8. A method of calculating a measure of the distance between a transmitter (1) and a receiver (12), the method comprising at the receiver (12):
receiving a signal transmitted by the transmitter (1);
determining the local time of reception of a reference point (30) in the signal;
receiving a message including:
an indication of a fraction of a sample period at the transmitter, the fraction being indicative of the timing of the reference point (30) relative to a sampling point (31), or
an indication of the value (34) of a register (24) in an NCO (17) of the transmitter (1) at a sampling point (32) following the reference point (30) and a sampling increment of the NCO;
using the message to derive a clock time at the transmitter at the reference point; and
using the derived transmitter clock time and the local reference point reception time to calculate the measure of the distance between the transmitter (1) and the receiver (12).

9. The method of claim 1, wherein the signal includes a PRN code having a chip period related to the second frequency.

10. A device (1) comprising:
a source of oscillation (15) arranged to provide a sampling signal (26) at a first frequency,
a numerically controlled oscillator (NCO) (17) configured to use the sampling signal (26) to provide at an output an NCO output signal approximating a regular signal having a second frequency; and
a recorder (18) arranged to record the value (34) of a register in the NCO (17) at a time (32) derived from the sampling signal (26) and following a reference point (30), thereby to allow the reference point (30) in the signal to be identified.

11. The device of claim 10, further comprising a transmitter (8) arranged to transmit a signal derived from the NCO output signal.

12. The device of claim 10, further comprising a processor (2) arranged to use the recorded value (34) to derive the local device clock time at the reference point (30).

13. The device of claim 10, further comprising a processor (2) arranged to prepare a message for transmission to a receiver device (12), wherein the message comprises information enabling the receiver device (12) to derive the clock time of the transmitter (1) at the reference point (30).

14. A device of claim 13, wherein the processor (2) is further arranged to use the recorded value (34) to determine a fraction of a sampling period at the device indicative of the timing of the reference point (30) relative to a sampling point (31), and to include an indication of the fraction in the information.

15. A device of claim 13, wherein the processor (2) is further arranged to include an indication of the recorded value (34) and a sampling increment of the NCO (17) in the information.

16. A system for calculating a measure of the distance between a transmitter (1) and a receiver device (12),
the transmitter (1) being a device as claimed in claim 11, and
the receiver (12) comprising:
receiver means (122) for receiving the transmitted signal;
a processor (123, 126) arranged to determine the local time of reception of the reference point (30) in the signal;
the receiver (12) being arranged either:
to receive from the transmitter (1) an indication of a clock time at the transmitter at the reference point; or
to receive from the transmitter a message including:
an indication of a fraction of a sample period at the transmitter, the fraction being indicative of the timing of the reference point relative to a sampling point (31), or
an indication of the value of the register (34); and
the receiver (12) being arranged to use the message to derive a clock time at the transmitter (1) at the reference point (30); and
the processor (123, 126) being arranged to use the transmitter clock time and the local reference point reception time to calculate the measure of the distance between the transmitter and the receiver.

17. A receiver device (12) operable to calculate a measure of the distance between a transmitter (1) and the receiver device (12) from a received signal transmitted by the transmitter, the receiver device comprising:
a processor (23, 26) arranged to determine the local time of reception of a reference point (30) in the signal;
a receiver (122) arranged to receive from the transmitter a message including:
an indication of a fraction of a sample period at the transmitter, the fraction being indicative of the timing of the reference point (30) relative to a sampling point (31), or
an indication of the value (34) of a register (24) in an NCO (17) of the transmitter (1) at a sampling point (32) following the reference point and a sampling increment of the NCO;
the processor (23, 26) being arranged to use the message to derive a clock time at the transmitter at the reference point, and to use the derived transmitter clock time and the local reference point reception time to calculate the measure of the distance between the transmitter (1) and the receiver (12).
